(19) United States
(12) Patent Application Publication
(10) Pub. No.: US 2010/0327314 A1
(43) Pub. Date: Dec. 30, 2010

(54) Insulated Gate Bipolar Transistor (IGBT) Collector Formed with Ge/A1 and Production Method

(76) Inventors: Ping Huang, Shanghai (CN); Tao Feng, Santa Clara, CA (US); Ruisheng Wu, Shanghai (CN); Yi Chen, Shanghai (CN); Lei Duan, Shanghai (CN)

Correspondence Address: CHEIN-HWA S. TSAO, 6684 MT PAKRON DRIVE, SAN JOSE, CA, 95120, US

(21) Appl. No.: 12/493,226

(22) Filed: Jun. 28, 2009

(51) Int. Cl. H01L 29/739; H01L 21/20

(52) U.S. Cl. 257/139; 438/507; 438/135; 257/E29.197; 257/E21.09

(57) ABSTRACT

This invention discloses an IGBT device with its collector formed with Ge/Al and associated method of fabrication. The collector is formed on the substrate layer, which is on the back of IGBT, and contains Ge and Al thin films. After thinning and etching the back side of IGBT substrate, Ge and Al are sequentially deposited to form Ge/Al thin films on the back surface of the substrate. An annealing process is then carried out to diffuse Al into Ge thin film layer to form a P-doped Ge layer functioning as the IGBT collector. The present invention is applicable to both non punch through IGBTs as well as punch through IGBTs.

### CROSS REFERENCE TO RELATED APPLICATIONS

### Field of Invention

This invention relates generally to the field of semiconductor electronics. More specifically, the present invention is directed to the structural design and fabrication of a semiconductor device.

### BACKGROUND OF THE INVENTION

During an insulated gate bipolar transistor (IGBT) manufacturing process a collector is formed on the back side of silicon substrate. Currently both non punch through type and punch through type IGBTs utilize back side ion implantation method to implant dopants, of opposite conductivity type to the substrate dopants, onto a silicon substrate back surface to counter dope the substrate and then heat anneal it to activate the implanted dopants thus forming a collector. As a result, this requires expensive ion implantation equipment and complicated process control.

For instance, U.S. Pat. No. 7,005,702 discloses a non punch through type IGBT with transparent amorphous silicon collector or anode structure formed on a float zone silicon wafer by depositing a P-type doped amorphous silicon layer on the back surface of an ultra thin wafer.

In another example, U.S. Pat. No. 6,242,288 discloses a method of making a non punch through type IGBT with weak collector (anode). The collector (anode) of a non punch through IGBT formed in a float zone silicon monocrystaline wafer is formed with a DMOS top structure and is thereafter ground at its bottom surface to a thickness of less than 250 micron. A shallow P type implant is then made into the bottom surface and the wafer is then heated in vacuum to about 400° C. for about 30 to 60 seconds to remove moisture and other contaminants from the bottom surface. An aluminum layer is then sputtered onto the bottom surface, followed by other metals to form the bottom electrode. No activation anneal is necessary to activate the weak collector junction. However, due to the use of Al as P-type impurity in this method, it brings about two problems. One problem is that contact resistance is high, which consequently leads to higher device voltage drop when the IGBT is turned on. Another problem is that the higher injection efficiency of cavity leads to an undesirable increase of IGBT turn-off time.

In summary, existing structures and production methods of IGBTs use ion implantation machine to implant P-type dopants into back surface of silicon substrate to form IGBT collector and this incurs high cost. It is therefore desirable to develop a new IGBT collector structure and fabrication method, applicable to both non punch through and punch through IGBTs, that can provide the benefit of simplified production process, improved manufacturing efficiency, lower production cost and higher product performance.

### SUMMARY OF THE INVENTION

An object of the present invention is to provide an IGBT collector formed with Ge/Al thin films and its fabrication method that is applicable to both non punch through and punch through IGBTs. The method should effectively reduce production cost and improve device parameter performance of the IGBT product.

To achieve the above object, the present invention provides an IGBT collector formed with Ge/Al thin film layers on the back surface of an IGBT substrate. The collector includes a Ge thin film formed directly on the back surface of the IGBT substrate and an Al thin film overlaying the Ge thin film. In one embodiment the Ge thin film is made in contact with a lightly doped drift region extending to the back side of a silicon substrate. In a second embodiment the Ge thin film is made in contact with a heavily doped buffer layer disposed at the back surface of the silicon substrate. In a more detailed embodiment the Ge thin film has a thickness ranging from 50-5000 A (Angstrom). In another detailed embodiment the Al thin film has a thickness ranging from 100-10000 A. In yet another embodiment the IGBT further includes Ti, Ni and Ag thin films overlaying the Al thin film.

Thus, aluminum from the Al thin film diffuses into the Ge thin film to form a P-type Ge thin film layer that functions as an IGBT collector. In one embodiment the Ge thin film has a dopant density of Al in Ge thin film in the range of 10¹⁸˜10²¹ cm⁻³. The P-type Ge thin film is formed on the back surface of an N-type substrate layer. The N-type substrate layer may further include an N+ buffer layer on its back surface.

The present invention also provides a method of making the Ge/Al IGBT collector with the following steps:
Provide a silicon substrate with top portion structure of an IGBT formed on it through front surface of the silicon substrate.
Reduce the substrate thickness by thinning and etching the back surface of silicon substrate.
Deposit Ge on the back surface of thus thinned silicon substrate to form a Ge thin film layer on it.
Deposit Al on the back surface of thinned silicon substrate to form an Al thin film layer overlaying the already formed Ge thin film layer.

The method can include a subsequent step of annealing the formed Ge/Al thin films to diffuse aluminum into the Ge thin film thus forming a P-doped Ge layer.

The Ge thin film and the Al thin film may be formed with a number of methods.
The first method is by evaporating Ge/Al that includes:
   Firstly, evaporate Ge metal on the back surface of silicon substrate to form a Ge thin film; and
   Subsequently, evaporate Al metal on back surface of the substrate to form an Al thin film overlaying the already formed Ge thin film.
The second method is by sputtering Ge/Al that includes:
   Firstly, sputter Ge metal on the back surface of silicon substrate to form a Ge thin film; and
   Subsequently, sputter Al metal on back surface of the substrate to form an Al thin film overlaying the already formed Ge thin film.
The third method is by successively implanting Ge and depositing Al and that includes:
   Firstly, implant Ge on the back surface of silicon substrate to form a Ge thin film; and
   Subsequently, deposit Al metal on back surface of the substrate to form an Al thin film overlaying the already formed Ge thin film.
   The step of annealing the Ge and Al thin films may be accomplished with a number of methods.
The first method involves annealing the Ge and Al thin films in a vacuum chamber, with annealing temperature ranges from room temperature (25° C.)˜400° C., preferably between 200° C.˜400° C., and annealing time from 30 sec˜120 min, preferably between 10 min˜60 min. The associated annealing time depends upon the thickness of Ge thin film and injection efficiency of cavity.
The second method involves annealing the Ge and Al thin films with a gas mixture of nitrogen and hydrogen in a furnace tube, with an annealing temperature between 300° C.˜450° C., preferably between 350° C.˜450° C., and annealing time from 10 min˜120 min, preferably between 10 min˜60 min. The associated annealing time depends upon thickness of Ge thin film and injection efficiency of cavity.
The third method involves laser annealing of the Ge and Al thin films.

The present invention IGBT provides a collector formed with Ge/Al thin films. As the band gap of Ge is narrower than that of Si, the barrier height across the P—Ge/Al interface is lower than that of the P—Si/Al interface of prior arts. Consequently, the contact resistance of P—Ge/Al is lower than that of P—Si/Al, this beneficially reduces device voltage drop when the IGBT is turned on. In addition, as the band gap of Ge is narrower than that of Si, the injection efficiency of PNP-type IGBT formed with Ge/Al collector will be lower than that of conventional Si—PNP-type IGBT. Therefore the IGBT turn-off time of the present invention is beneficially shortened. Thus, the application of a Ge/Al collector provides an IGBT with improved conduction resistance and turn-off time at the same time over prior arts. The injection efficiency of cavity can be further adjusted by tuning the thickness of Ge thin film or annealing parameters during manufacturing process, such as efficiency, temperature and time, etc., to further optimize the performance of IGBT.

In essence, the present invention discloses an IGBT collector formed with Ge/Al and its fabrication method. The present invention is applicable to non punch through as well as punch through type IGBTs with the benefit of simplified manufacturing process, reduced manufacturing cost and improved device performance parameters.

### BRIEF DESCRIPTION OF THE DRAWINGS

In order to more fully describe numerous embodiments of the present invention, reference is made to the accompanying drawings. However, these drawings are not to be considered limitations in the scope of the invention, but are merely illustrative.

FIG. 1 is a cross sectional view of a non punch through IGBT with its substrate back surface processed ready for formation of collector according to the present invention;

FIG. 2 is a cross sectional view of an IGBT of FIG. 1 with collector formed according to the present invention;

FIG. 3 is a cross sectional view of an alternative embodiment of the IGBT of FIG. 2;

FIG. 4 is a cross sectional view of a punch through IGBT with its substrate back surface processed ready for formation of collector according to the present invention;

FIG. 5 is a cross sectional view of an IGBT of FIG. 4 with collector formed according to the present invention; and

FIG. 6 is a cross sectional view of an alternative embodiment of the IGBT of FIG. 5.

### DETAILED DESCRIPTION OF SPECIFIC EMBODIMENTS

The description above and below plus the drawings contained herein merely focus on one or more currently preferred embodiments of the present invention and also describe some exemplary optional features and/or alternative embodiments. The description and drawings are presented for the purpose of illustration and, as such, are not limitations of the present invention. Thus, those of ordinary skill in the art would readily recognize variations, modifications, and alternatives. Such variations, modifications and alternatives should be understood to be also within the scope of the present invention.

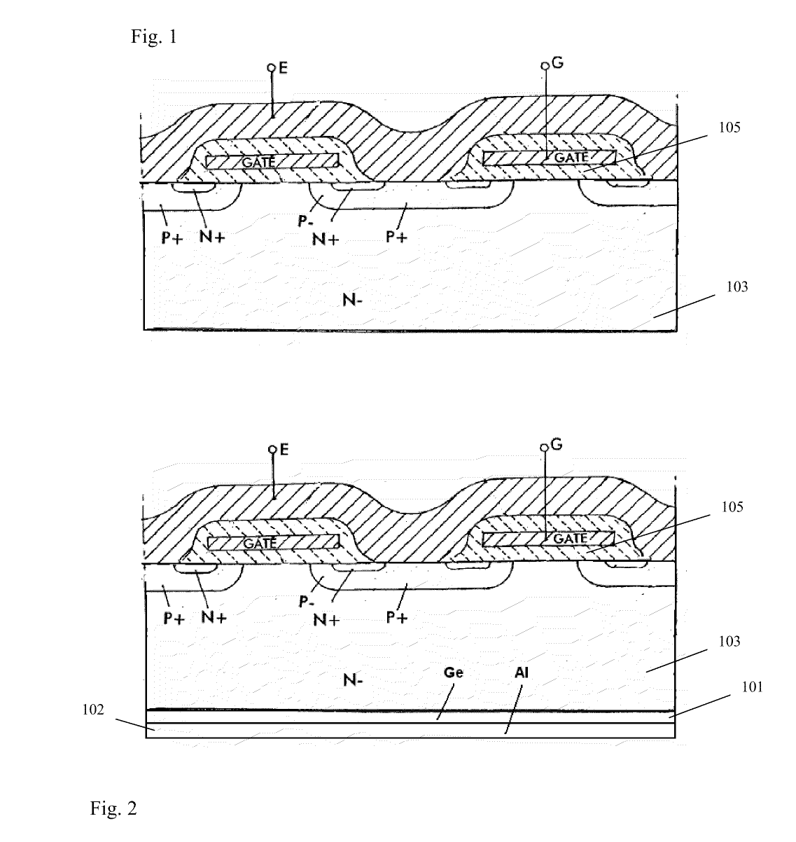

As illustrated in FIG. 2, the structure of a non punch through IGBT is formed on the top of an N− type Si substrate layer 103(drift region). There is an N+ type source region of high dopant density disposed on a top surface of the Si substrate and surrounded by a P-channel region. A P+ type source electrode shorting region of high dopant density is provided to improve the body-source metal contact. An insulated gate formed with a conductive material is disposed on top of a gate dielectric layer 105 covering the top surface of silicon substrate. A Ge thin film layer is disposed at back surface of the silicon substrate and in contact with the N− drift region. The Ge thin film layer is further covered by an Al metal layer. The Ge thin film becomes doped into P type by Al due to diffusion of the overlaying Al layer. Contact electrodes are connected to the N+ source region, the P+ source electrode shorting region, the insulated gate above the P-channel region and the Ge/Al thin films on the back surface of N− type substrate layer with good electric conductivity. These electrodes become cathode (emitter), gate and anode (collector) of a thus formed vertical non punch through IGBT.

The collector structure of this non punch through IGBT, formed by Ge/Al on back side of the N-substrate layer 103, includes:
A Ge thin film 101 located on the back surface of the substrate layer.
An Al thin film 102 that overlays the Ge thin film.

The fabrication of this collector structure includes the following steps:

A1) As illustrated in FIG. 1, after making the top portion structure of IGBT on a silicon substrate through the front surface, thinning and etching the N− type substrate layer 103 on the back of silicon substrate to reduce the substrate thickness. In one embodiment, the thickness of silicon substrate is thinned from about 720 μm to a required thickness of 50 μm˜200 μm. Concurrently, the damaged layer and wearing layer on back of the silicon substrate are also removed through etching.

A2) As illustrated in FIG. 2, after thinning and etching the N− type substrate layer 103 on the back of IGBT silicon substrate, sequentially forming a Ge thin film 101 and an Al thin film 102 on back surface of the N-substrate layer 103. This step further includes:
A21) Evaporating Ge metal on the back surface of the N-substrate layer 103 to form a Ge thin film 101.
A22) Evaporating Al metal on the back surface of the silicon substrate to form an Al thin film 102 overlaying the already formed Ge thin film.

As an alternative, the above Ge and Al thin films can be formed by successively sputtering or implanting Ge then depositing Al. In any case, the resulting thickness of Ge thin film 101 may be in the range of 50 A˜5000 A and the thickness of Al thin film 102 may be in the range of 100 A˜10000 A.
A23) Annealing the thus formed Ge and Al thin films such that the Al from the Al thin film diffuses into the Ge thin film forming an Al doped Ge layer.

The above annealing process can be accomplished by several different methods as described below:

In a first method the substrate with formed Ge/Al thin films is annealed in a vacuum chamber with annealing temperature range between 25° C. and 400° C., preferably between 200° C. and 400° C., and annealing time from 30 sec˜120 min, preferably from 10 min˜60 min. In one embodiment, the Ge and Al thin films are annealed at a temperature between 250° C. and 280° C. in vacuum chamber. The annealing time should be chosen depending upon the thickness of Ge thin film and a desired injection efficiency of cavity.

The second method is to anneal the Ge and Al thin films with a gas mixture of nitrogen and hydrogen in a furnace tube, with annealing temperature in the furnace tube range between 300° C. and 450° C., preferably between 350° C. and 450° C., and annealing time from 10 min˜120 min, preferably 10 min˜60 min. In one embodiment, the substrate with Ge and Al thin films is annealed at a temperature between 350° C. and 380° C. in the furnace tube. The annealing time should be chosen depending upon the thickness of Ge thin film and a desired injection efficiency of cavity.

The third method is laser annealing of the Ge and Al thin films.

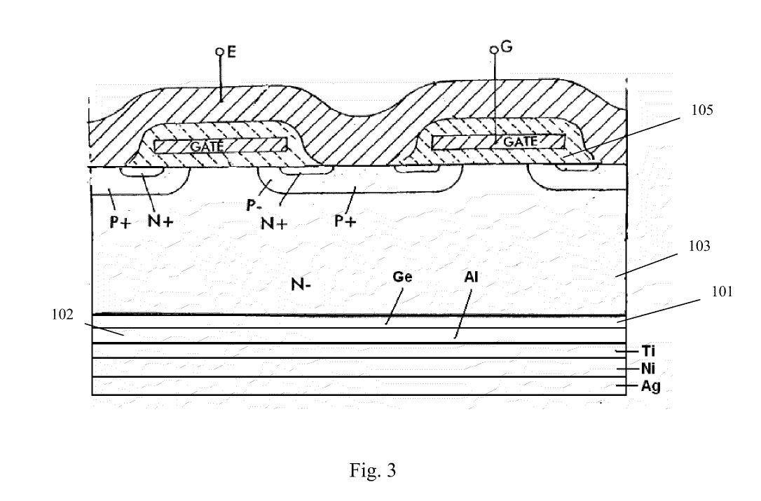

A24) As illustrated in FIG. 3, Ti, Ni and Ag thin films may be successively deposited on the surface of Al thin film to form the collector electrode.

The annealing process, as disclosed in step A23) above, drives Al into the Ge thin film via diffusion. As Al is a group III element, it forms a P-type dopant in the Ge thin film thus turning it into an IGBT collector (anode). In general, the higher the diffusion density of Al in Ge thin film the higher the resulting injection efficiency of cavity will be. This leads to a lower IGBT conduction resistance while compromising its turn-off time (made longer). On the other hand, the lower the diffusion density of Al in Ge thin film, the lower the resulting injection efficiency of cavity will be. This leads to a higher IGBT conduction resistance while beneficially shortening its turn-off time. Consequently, a trade off between on resistance and turn-off time of an IGBT can be made by adjusting thickness of the Ge thin film and its annealing conditions. Generally, the dopant density of Al in Ge thin film should be in the range of 10¹⁸˜10²¹ cm⁻³.

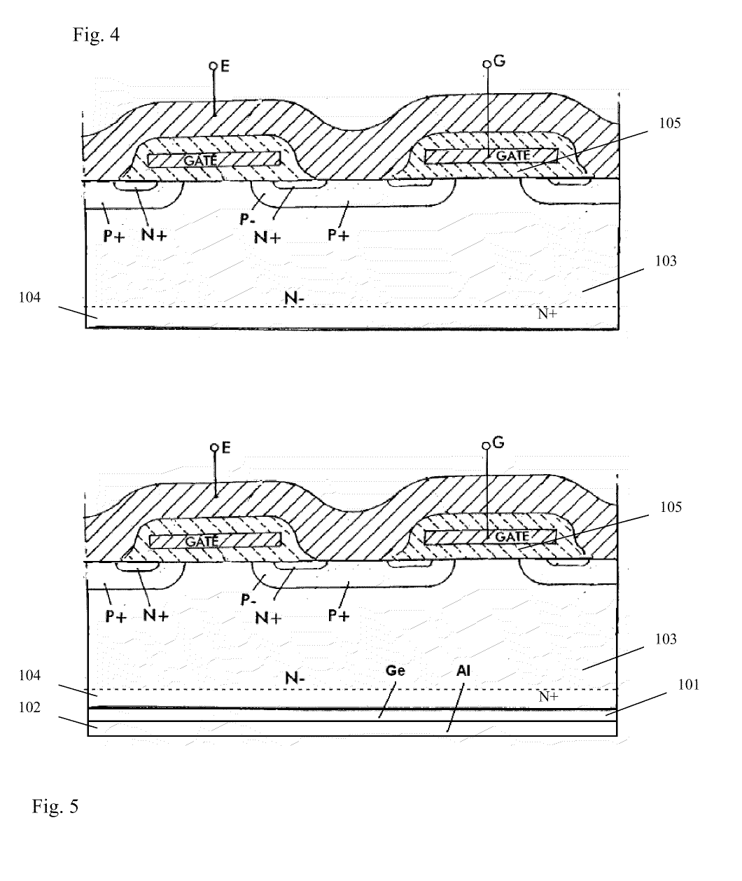

Turning now to FIG. 4 through FIG. 6 for the embodiments of a punch through IGBT according to the present invention. The difference between non punch through IGBT and punch through IGBT is that, for a punch through IGBT there is an N+ buffer layer 104 on the back surface of the N-type substrate layer. That is, the N+ buffer layer forms the back surface of the substrate.

As illustrated in FIG. 5, under the present invention, the collector of a punch through IGBT is formed with Ge/Al is on the back surface of substrate layer. The Ge/Al includes:
A Ge thin film 101 formed directly on the back surface of substrate layer.
An Al thin film 102 overlaying the Ge thin film.

The fabrication of this collector includes the following steps:

B1) As illustrated in FIG. 4, after making the front portion structure of IGBT on a silicon substrate through the front surface, thinning and etching the N− type substrate layer on the back of silicon substrate. In one embodiment, the thickness of silicon substrate is thinned from about 720 μm to a required thickness of 50 μm˜200 μm. Concurrently, the damaged layer and wearing layer on back of the silicon substrate are also removed through etching. Next, an N+ buffer layer 104 is formed by implanting N type dopants into the back surface of the N− type substrate layer 103 located on the back of silicon substrate. The N type dopants are then activated by annealing to form the N+ buffer layer 104. Alternatively, the silicon substrate may contain a thin N− epi drift layer on top of a thick N+ layer and the N+ layer is thinned to form the buffer layer 104 after the top portion structure of the IBGT is formed through the front surface.

B2) As illustrated in FIG. 5, after thinning and etching the substrate layer on the back side of IGBT silicon substrate, sequentially forming a Ge thin film 101 and an Al thin film 102 on back surface of the substrate layer 103. This step further includes:
B21) Evaporating Ge metal on the back surface of the N+ buffer layer 104 to form a Ge thin film 101.
B22) Evaporating Al metal on the back surface of N+ buffer layer 104 to form an Al thin film 102 overlaying the already formed Ge thin film 101.

As an alternative, the above Ge and Al thin films can be formed by successively sputtering or implanting Ge then depositing Al. In any case, the resulting thickness of Ge thin film 101 may be in the range of 50 A˜5000 A and the thickness of Al thin film 102 may be in the range of 100 A˜10000 A.
B23) Annealing the thus formed Ge and Al thin films such that the Al from the Al thin film diffuses into the Ge thin film forming an Al doped Ge layer.

The above annealing process can be accomplished by several different methods as described below:

In a first method the substrate with formed Ge/Al thin films is annealed in a vacuum chamber with annealing temperature range between 25° C. and 400° C., preferably between 200° C. and 400° C., and annealing time from 30 sec˜120 min, preferably from 10 min˜60 min. In one embodiment, the Ge and Al thin films are annealed at a temperature between 250° C. and 280° C. in vacuum chamber. The annealing time should be chosen depending upon the thickness of Ge thin film and a desired injection efficiency of cavity.

The second method is to anneal the Ge and Al thin films with a gas mixture of nitrogen and hydrogen in a furnace tube, with annealing temperature in the furnace tube range between 300° C. and 450° C., preferably between 350° C. and 450° C., and annealing time from 10 min˜120 min, preferably 10 min˜60 min. In one embodiment, the substrate with Ge and Al thin films is annealed at a temperature between 350° C. and 380° C. in the furnace tube. The annealing time should be chosen depending upon the thickness of Ge thin film and a desired injection efficiency of cavity.

The third method is laser annealing of the Ge and Al thin films.

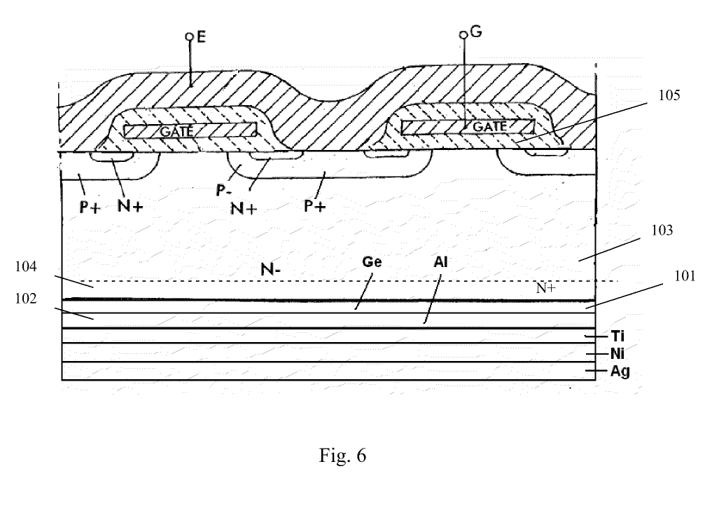

B24) As illustrated in FIG. 6, Ti, Ni and Ag thin films may be successively deposited on the surface of Al thin film to form the collector electrode.

As described before, the annealing process of step B23) also drives Al into the Ge thin film via diffusion to form a P-type dopant in the Ge thin film thus turning it into an IGBT collector (anode). In general, the higher the diffusion density of Al in Ge thin film the higher the resulting injection efficiency of cavity will be. This leads to a lower IGBT conduction resistance while compromising its turn-off time (made longer). On the other hand, the lower the diffusion density of Al in Ge thin film, the lower the resulting injection efficiency of cavity will be. This leads to a higher IGBT conduction resistance while beneficially shortening its turn-off time. Consequently, a trade off between on resistance and turn-off time of an IGBT can be made by adjusting thickness of the Ge thin film and its annealing conditions. Generally, the dopant density of Al in Ge thin film should be in the range of 10¹⁸˜10²¹ cm⁻³.

The IGBT of the present invention provides a collector formed with Ge/Al thin films. As the band gap of Ge is narrower than that of Si, the barrier height across a P—Ge/Al interface is lower than that of P—Si/Al interface of prior arts. As a result, contact resistance of P—Ge/Al is lower than that of P—Si/Al and this beneficially reduces device voltage drop when the IGBT is turned on. In addition, also due to the band gap of Ge being narrower than that of Si, the injection efficiency of a PNP-type IGBT formed with Ge/Al collector will be lower than that of a conventional Si—PNP-type IGBT. Therefore the turn-off time of the present invention IGBT will be shortened as well. In essence, using a Ge/Al collector provides an IGBT with improved conduction resistance and turn-off time at the same time over prior arts. The injection efficiency of cavity can be further adjusted by tuning the thickness of Ge thin film or annealing condition in the fabrication process, such as efficiency, temperature and time etc., to further optimize the performance parameters of IGBT.

The present invention provides an IGBT with its collector formed with Ge/Al and associated method of fabrication. The present invention, being applicable to non punch through as well as punch through IGBTs, provides the benefit of simplified manufacturing process, reduced manufacturing cost and improved device performance parameters. While the illustrated figures focus on the structure of planar IGBT devices, to those skilled in the art IGBT devices of other structural types, such as trenched gate IGBTs, can similarly benefit from the present invention.

Although the foregoing embodiments have been described in some detail for purposes of clarity of understanding, the scope of the present invention is not limited to these details. Within the scope of the present invention numerous alternative ways exist for its implementation. Thus, the disclosed embodiments are merely illustrative but not restrictive.

What is claimed are:

1. An Insulated Gate Bipolar Transistor (IGBT) semiconductor device comprising a collector formed on a silicon substrate back surface, wherein the collector further comprises:
a Ge thin film disposed at the back surface of the silicon substrate; and
an Al thin film overlaying the Ge thin film.

2. The IGBT of claim 1 wherein the Ge thin film is doped with aluminum thereby forming a P-type Ge thin film as the IGBT collector.

3. The IGBT of claim 2 further comprising a drift region extending to the back surface of the silicon substrate with the Ge thin film in contact with the drift region.

4. The IGBT of claim 2 further comprising a buffer layer disposed at the back surface of the silicon substrate with the Ge thin film in contact with the buffer layer.

5. The IGBT of claim 2 wherein the Ge thin film has a thickness range from 50-5000 A (angstrom).

6. The IGBT of claim 2 wherein the Al thin film has a thickness range from 100-10000 A.

7. The IGBT of claim 2 wherein the Ge thin film has a dopant density of Al in the range of 10¹⁸˜10²¹ cm⁻³.

8. The IGBT of claim 2 further comprising Ti, Ni and Ag thin films overlaying the Al thin film.

9. A method of making an Insulated Gate Bipolar Transistor (IGBT) comprises the steps of:
providing a silicon substrate with a top portion structure of IGBT formed on the front surface of the silicon substrate;
reducing the substrate thickness by thinning and etching the back surface of the silicon substrate;
depositing Ge on the back surface of the silicon substrate to form a Ge thin film layer; and
depositing Al on the back surface of the silicon substrate to form an Al thin film layer overlaying the already formed Ge thin film layer.

10. The method of claim 9 further comprises annealing the formed Ge/Al thin films to drive the Al via diffusion into the Ge thin film thereby forming a P-doped Ge layer.

11. The method of claim 10 wherein the step of depositing Ge thin film layer further comprises evaporating Ge.

12. The method of claim 10 wherein the step of depositing Ge thin film layer further comprises sputtering Ge.

13. The method of claim 10 wherein the step of depositing Ge thin film layer further comprises implanting Ge.

14. The method of claim 10 wherein the step of annealing further comprises annealing the Ge/Al thin films in a vacuum chamber, at an annealing temperature between about 25° C. and about 400° C. and annealing time between about 30 sec and about 120 min.

15. The method of claim 10 wherein the step of annealing further comprises annealing the Ge/Al thin films in a furnace tube, with annealing temperature in range of about 300° C. to about 450° C., and annealing time between about 10 min to about 120 min.

16. The method of claim 15 wherein annealing the Ge/Al thin films further comprises annealing them with a gas mixture of nitrogen and hydrogen.

17. The method of claim 9 wherein the step of reducing the substrate thickness further comprises thinning and etching the back surface of silicon substrate into a lightly doped drift region of IGBT.

18. The method of claim 17 further comprises implanting a dopant into back surface of the substrate to form a heavily doped buffer layer at the back surface.

19. The method of claim 9 wherein the step of reducing the substrate thickness further comprises thinning and etching the back surface of silicon substrate into a heavily doped buffer layer of IGBT.
